(19) United States
(12) Patent Application Publication
(10) Pub. No.: US 2010/0225377 A1
(43) Pub. Date: Sep. 9, 2010

(54) SWITCH CIRCUIT

(75) Inventor: Tomonori OKASHITA, Kanagawa (JP)

Correspondence Address: YOUNG & THOMPSON, 209 Madison Street, Suite 500, Alexandria, VA, 22314, US

(73) Assignee: NEC ELECTRONICS CORPORATION, Kanagawa (JP)

(21) Appl. No.: 12/718,661

(22) Filed: Mar. 5, 2010

(30) Foreign Application Priority Data
Mar. 6, 2009 (JP) 2009-054085

(51) Int. Cl. H03K 17/687

(52) U.S. Cl. 327/427

(57) ABSTRACT

A switch circuit includes an input section; an output section; a first series section having an output and comprising at least a first 4-terminal FET connected between the input section and the output section through the output of the first series section; a first shunt section comprising at least a second 4-terminal FET connected between an output of the first series section and a ground; a first control terminal section connected with a gate of the first 4-terminal FET; a second control terminal section connected with a gate of the second 4-terminal FET; and a back gate control terminal section connected with a back gate of each of the first and second 4-terminal FETs. A bias power supply section is configured to apply a reverse bias voltage between the back gate control terminal section and the ground.

### INCORPORATION BY REFERENCE

This application claims a priority on convention based on Japanese Patent Application No. 2009-054085. The disclosure thereof is incorporated herein by reference.

### TECHNICAL FIELD

The present invention relates to a switch circuit and a matrix switch circuit using the switch circuit, and particularly relates to a switch circuit used for switching a high frequency signal and a matrix switch circuit using the switch circuit.

### BACKGROUND ART

In recent years, microwave in a GHz band has been used in a mobile communication equipment such as a mobile phone terminal. A semiconductor switch is used in a high frequency switching section such as an antenna switching circuit. A semiconductor switch using a GaAs field effect transistor and a semiconductor switch using a silicon MOSFET (Metal Oxide Semiconductor Field-Effect transistor) are generally used as the semiconductor switch.

Among these semiconductor switches, the silicon MOSFET is a four-terminal device, including a back gate, while the GaAs field effect transistor is a three-terminal device. A source-back gate parasitic PN junction diode is further included between the back gate and a source. Similarly, a drain-back gate parasitic PN junction diode is included between the back gate and a drain. Therefore, when an AC signal with a large amplitude is inputted to the switch circuit, the AC signal is applied in a direction to turn on these parasitic diodes. As a result, it becomes impossible to keep a linear operation of the switch circuit when the voltage amplitude of the AC signal is increased, resulting in degradation of an insertion loss characteristic and a distortion characteristic.

In conjunction with the above description, Japanese Patent No. 2964975 discloses a high frequency switch circuit. The high frequency switch circuit controls a gate voltage of a transistor having a drain, a source, a gate and a back gate, to connect the drain and the source or to disconnect the drain from the source. In the high frequency switch circuit, a resistor is connected between the back gate and the ground.

Also, Japanese patent publication (JP 2003-347553A) discloses a high frequency circuit device. The high frequency circuit device includes a plurality of FETs on a surface silicon layer. The surface silicon layer is formed on a substrate via an insulating film to have an SOI structure. The plurality of FETs is formed in respective well regions which are separated from each other by a trench formed in the surface silicon layer. Each of the well regions is grounded via a resistor arranged in the surface silicon layer.

FIG. 1 is a circuit diagram of a conventional high frequency SPST (Single-Pole/Single-Throw) switch circuit. The conventional high frequency SPST switch circuit includes an input node 11, an output node 14, a first control node 12, a second control node 13, a first FET 15, a second FET 16, and four resistors 121, 122, 131 and 132. Here, the first FET 15 and the second FET 16 are used as a series FET and a shunt FET, respectively.

The input node 11 is connected to a drain of the series FET 15. The output node 14 is connected to a source of the series FET 15 and a drain of the shunt FET 16. A source of the shunt FET 16 is grounded. The first control node 12 is connected to a gate of the series FET 15 via the first resistor 121. The second control node 13 is connected to a gate of the shunt FET 16 via the second resistor 131. A back gate of the series FET 15 and a back gate of the shunt FET 16 are grounded via the third resistor 122 and the fourth resistor 132, respectively.

In the conventional switch circuit shown in FIG. 1, an ON state of the SPST switch circuit is realized by turning on the series FET 15 and turning off the shunt FET 16. However, in the conventional switch circuit, an insertion loss characteristic and a distortion characteristic are degraded as a voltage amplitude of an input AC signal is increased.

FIG. 2 is a circuit diagram of an equivalent circuit when the ON state of the switch circuit shown in FIG. 1 is realized. Here, the equivalent circuit of the series FET corresponds to a single on-resistor. Also, the equivalent circuit of the shunt FET includes a gate capacitor, a source-back gate parasitic diode and a drain-back gate parasitic diode.

An operation of the conventional switch circuit shown in FIG. 1 will be described with reference to FIG. 2.

FIG. 3 is a graph to show a node voltage in the conventional switch circuit shown in FIG. 1. Assuming that a voltage amplitude of an input AC signal is Vs, an AC voltage with the voltage amplitude of Vs/2 is applied to the gate and the back gate of the shunt FET in an OFF state, as shown in FIG. 3.

Now, it is assumed that turn-on voltage of parasitic diodes 263 and 264 is +0.7 V. In this case, a maximum value (+Vs/2) of the voltage of the input AC signal applied to the back gate exceeds +0.7 V, the source-back gate parasitic diode and the drain-back gate parasitic diode are turned on. As a result, the shunt FET cannot keep the OFF state, resulting in generation of a conduction path between the input node and the ground. Thus, the insertion loss characteristic and the distortion characteristic are largely degraded in the conventional switch circuit.

### SUMMARY OF THE INVENTION

In an aspect of the present invention, a switch circuit includes an input section; an output section; a first series section having an output and comprising at least a first 4-terminal FET connected between the input section and the output section through the output of the first series section; a first shunt section comprising at least a second 4-terminal FET connected between an output of the first series section and a ground; a first control terminal section connected with a gate of the first 4-terminal FET; a second control terminal section connected with a gate of the second 4-terminal FET; and a back gate control terminal section connected with a back gate of each of the first and second 4-terminal FETs. A bias power supply section is configured to apply a reverse bias voltage between the back gate control terminal section and the ground.

In another aspect of the present invention, a matrix switch circuit includes n input sections, where n is an integer larger than 1; m output sections, where m is an integer larger than 1; a back gate control terminal section; a bias power supply section configured to apply a reverse bias voltage between the back gate control terminal section and the ground; (n×m) switch circuits; and (n×m) control terminals. An (i, j)^{th} (n≧i≧2, m≧j≧2) of the (n×m) switch circuits is connected with an i^{th} one of the n input sections, a j^{th} one of the m output sections, and an (i, j)^{th} one of the (n×m) control terminals. Each of the (n×m) switch circuits includes a first series section having an output and comprising at least a first 4-terminal FET connected between a corresponding one of the n input sections and a corresponding one of the m output sections through the output of the first series section; and a first shunt section comprising at least a second 4-terminal FET connected between an output of the first series section and a ground. A gate of each of the first and second 4-terminal FETS is connected with the back gate control terminal section.

A bias power source is arranged to apply, to the back gate, a voltage which enables to maintain a state of turning off the shunt FET even if an input AC signal voltage exceeds a threshold voltage by which the parasitic diode in the back gate is turned on.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a circuit diagram of a high frequency SPST switch circuit according to a conventional technique;

FIG. 2 is a circuit diagram of an equivalent circuit provided when a state of turning on is realized the SPST switch circuit of FIG. 1;

FIG. 3 is a graph to explain a node voltage in the SPST switch circuit of FIG. 1;

FIG. 4 is a graph to explain a node voltage in the high frequency SPST switch circuit according to a first embodiment of the present invention as shown in FIG. 5;

FIG. 5 is a circuit diagram of the high frequency SPST switch circuit according to the first embodiment of the present invention;

FIG. 6 is a circuit diagram of an equivalent circuit provided when a state of turning on is realized in the SPST switch circuit of FIG. 5;

FIG. 7 is a graph showing a result obtained by verifying an effect of a bias applied to a back gate control node according to the present invention using a circuit simulation;

FIG. 8 is a circuit diagram of a high frequency SPST switch circuit according to a second embodiment of the present invention;

FIG. 9 is a circuit diagram of a high frequency SPST switch circuit according to a third embodiment of the present invention;

FIG. 10 is a circuit diagram of a matrix switch circuit with n poles, m throws and n rows by m columns according to a fourth embodiment of the present invention;

FIG. 11 is a circuit diagram of a matrix switch circuit according to a fifth embodiment of the present invention; and

FIG. 12 is a circuit diagram of an SPST switch circuit according to a sixth embodiment of the present invention.

### DESCRIPTION OF EMBODIMENTS

Hereinafter, a high frequency switch circuit according to the present invention will be described in detail with reference to the attached drawings.

### First Embodiment

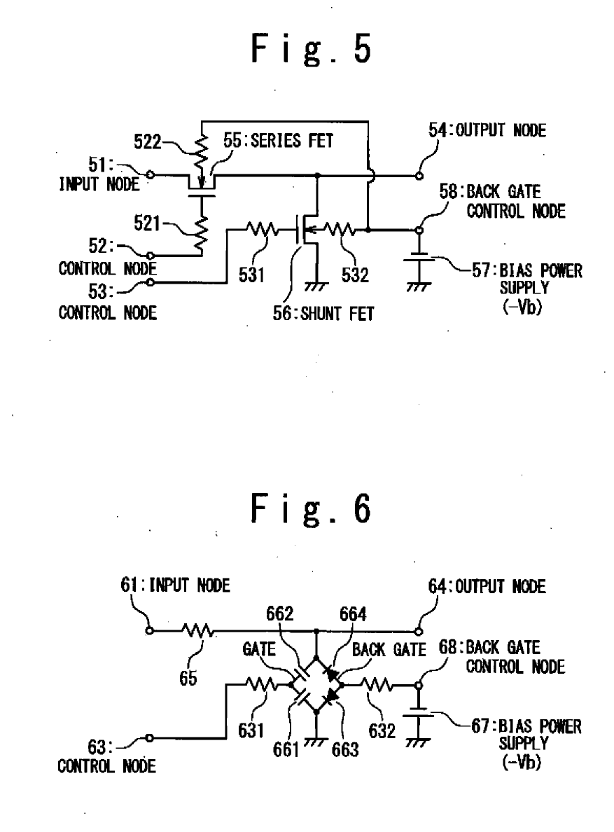

FIG. 5 is a circuit diagram of a high frequency SPST (Single-Pole/Single-Throw) switch circuit according to a first embodiment of the present invention. The SPST switch circuit includes an input terminal 51, an output terminal 54, a first control terminal 52, a second control terminal 53, a back gate control terminal 58, a first FET 55, a second FET 56, four resistors 521, 522, 531 and 532, and a bias power supply 57. Here, the first FET 55 and the second FET 56 are used as a series FET 55 and a shunt FET 56, respectively. The input terminal 51 is connected to a drain of the series FET 55. The output terminal 54 is connected to a source of the series FET 55 and a drain of the shunt FET 56. A source of the shunt FET 56 is grounded. The first control terminal 52 is connected to a gate of the series FET 55 via the first resistor 521. The second control terminal 53 is connected to a gate of the shunt FET 56 via the second resistor 531. A back gate of the series FET 55 and a back gate of the shunt FET 56 are connected to the back gate control terminal 58 via the third resistor 522 and the fourth resistor 532, respectively. The bias power supply 57 is connected to the back gate control terminal 58 to apply a reverse bias voltage. That is, a minus side node is connected to the terminal 58 and a plus side node of the bias power supply 57 is grounded.

In the SPST switch circuit in the first embodiment shown in FIG. 5, an ON state of the SPST switch circuit is realized when the series FET 55 is turned on and the shunt FET 56 are turned off.

FIG. 6 is a circuit diagram of an equivalent circuit when the ON state of the switch circuit shown in FIG. 5 is realized. This equivalent circuit includes an input terminal 61, an output terminal 64, a control terminal 63, a back gate control terminal 68, three resistors 65, 631 and 632, two capacitors 661 and 662, two diodes 663 and 664, and a bias power supply 67. Both ends of the resistor 65 are connected to the input terminal 61 and the output terminal 64. The control terminal 63 is connected to one of connection nodes of the resistor 631. The other connection node of the resistor 631 is connected to a connection node between the two capacitors 661 and 662. The other connection node of the capacitor 661 is connected to a cathode of the diode 663 and is grounded. The other connection node of the capacitor 662 is connected to the output terminal 64 and a cathode of the diode 664. An anode of the diode 663 is connected to an anode of the diode 664 and one of connection nodes of the resistor 632. The other connection node of the resistor 632 is connected to the back gate control terminal 68. The back gate control terminal 68 is connected to a connection node on a minus side of the bias power supply 67. A connection node on a plus side of the bias power supply 67 is grounded.

Here, the input terminal 51 in FIG. 5 corresponds to the input terminal 61 in FIG. 6. The output terminal 54 in FIG. 5 corresponds to the output terminal 64 in FIG. 6. The series FET 55 in FIG. 5 corresponds to the resistor 65 in FIG. 6. The second control terminal 53 in FIG. 5 corresponds to the control terminal 63 in FIG. 6. The second resistor 531 in FIG. 5 corresponds to the resistor 631 in FIG. 6. The shunt FET 56 in FIG. 5 corresponds to a group of the two capacitors 661 and 662 and the two diodes 663 and 664 in FIG. 6. In particular, the gate of the shunt FET 56 in FIG. 5 corresponds to a connection node to which the resistor 631 and the two capacitors 661 and 662 in FIG. 6 are connected. The back gate of the shunt FET 56 in FIG. 5 also corresponds to a connection node to which the two diodes 663 and 664 and the resistor 632 in FIG. 6 are connected. The back gate control terminal 58 in FIG. 5 corresponds to the back gate control terminal 68 in FIG. 6. The bias power supply 57 in FIG. 5 corresponds to the bias power supply 67 in FIG. 6.

It should be noted that the two capacitors 661 and 662 in FIG. 6 represent a gate capacitance in the shunt FET 56 of FIG. 5. The diode 663 in FIG. 6 represents a source-back gate parasitic diode in the shunt FET 56 of FIG. 5. The diode 664 in FIG. 6 further represents a drain-back gate parasitic diode in the shunt FET 56 of FIG. 5.

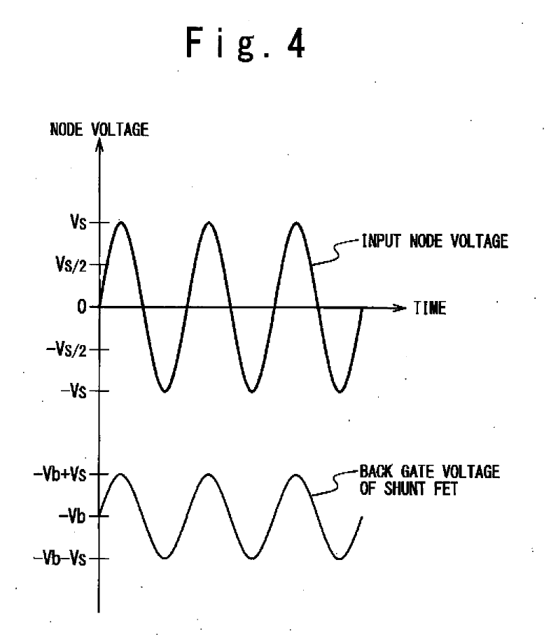

FIG. 4 is a graph showing a node voltage in the high frequency SPST switch circuit according to the first embodiment of the present invention as shown in FIG. 5. An operation of the SPST switch circuit in the first embodiment will be described with reference to the equivalent circuit shown in FIG. 6.

Now, assuming that a voltage amplitude of an input AC signal is Vs, an AC signal with the voltage amplitude of Vs/2 is applied to the gate and the back gate of the shunt FET 56 in the OFF state. However, the negative bias of −Vb is applied from the bias power supply 57 or 67 to the back gate control terminal 5B or 68. Therefore, the back gate voltage in the shunt FET 56 is expressed by −Vb+Vs/2.

Now, the ON voltage of the parasitic diode in the back gate is assumed to be +0.7 V. At this time, if the back gate voltage exceeds +0.7 V, the source-back gate parasitic diode and the drain-back gate parasitic diode are turned on. Accordingly, an insertion loss characteristic and a distortion characteristic are degraded in the SPST switch circuit. However, according to the present invention, the DC voltage in the back gate is biased to −Vb. Therefore, a voltage in the back gate when the input AC signal is applied changes taking −Vb as a center. As a result, the parasitic diodes are not turned on until −Vb+Vs/2 reaches +0.7 V.

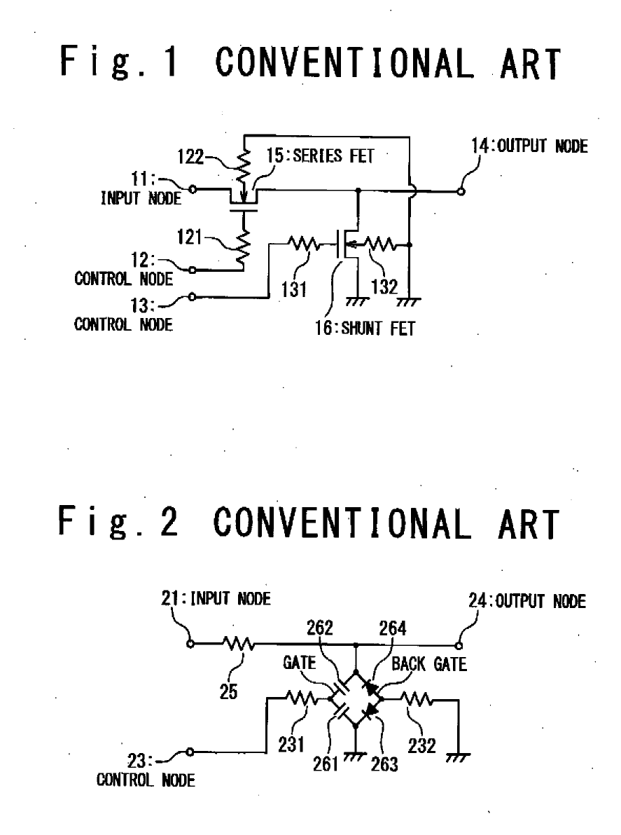

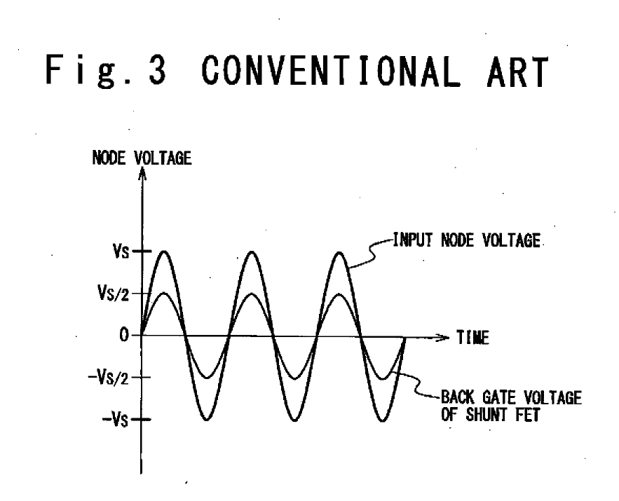

That is, in the present invention, the SPST switch circuit can keep a linear operation for an input AC signal with larger amplitude, unlike the conventional technique without negative bias application to the back gate control terminal. For example, in the conventional switch circuit shown in FIG. 1, when the voltage amplitude of an input signal is Vs, the voltage applied to the back gate of the shunt FET in the OFF state is ±Vs/2 as shown in FIG. 3. Now, assuming that the ON voltage of the parasitic diodes is +0.7 V, the input voltage amplitude Vs to allow the SPST switch circuit to perform a linear operation satisfies the following condition;

+Vs/2<+0.7V

namely, Vs<1.4 V.

In contrast, in the SPST switch circuit in the first embodiment shown in FIG. 5, assuming that the voltage amplitude of the input signal is Vs, the voltage amplitude applied to the back gate of the shunt FET in the OFF state satisfies the following condition (−Vb±Vs/2) as shown in FIG. 4. For example, if the back gate control terminal is biased to −Vb=−3 V, the condition of the input voltage amplitude to allow the switch circuit to perform a linear operation is expressed by

−3+Vs/2<+0.7V

namely, Vs<7.4 V

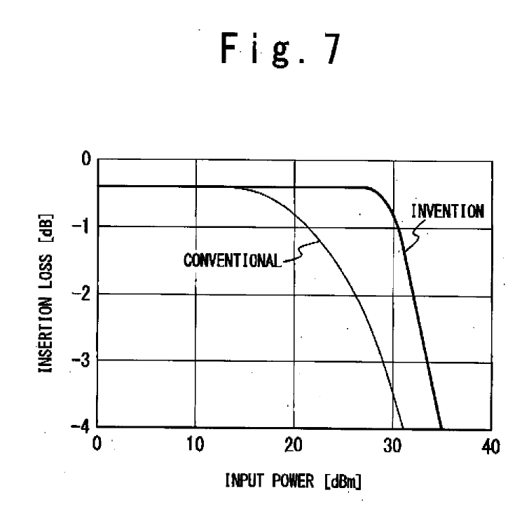

FIG. 7 shows graphs representing a circuit simulation result of an effect of the back gate control terminal bias according to the present invention. Here, a horizontal axis shows input power in unit of dBm. A vertical axis shows insertion loss in unit of dB. Two graphs correspond to the conventional SPST switch circuit and the SPST switch circuit according to the present invention.

Circuit diagrams of the conventional SPST switch circuit shown in FIG. 1 and the SPST switch circuit according to the first embodiment of the present invention shown in FIG. 5 were used. When the simulation was carried out on the condition that the bias power supply 57 or 67 is −Vb=−3 V, the simulation result was coincident with the above consideration.

It should be noted that application of the same bias voltage to both the series FET 55 and the shunt FET 56 is only an example and the present invention is not limited to this example. In other words, it is not necessarily required to apply the same bias voltage to both the FETs 55 and 56, and different bias voltages may be applied to the FETs 55 and 56.

### Second Embodiment

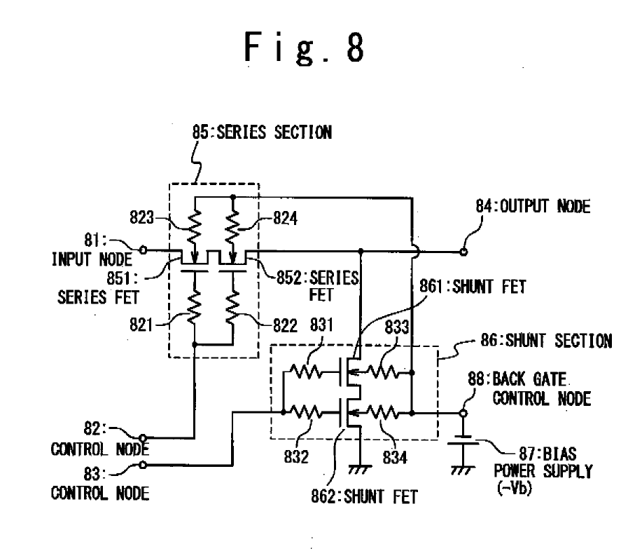

FIG. 8 is a circuit diagram of a high frequency SPST switch circuit according to a second embodiment of the present invention. The SPST switch circuit in the present embodiment is realized by replacing each of the series FET 55 and the shunt FET 56 shown in FIG. 5 with two FETs which are connected in serial. More specifically, the SPST switch circuit in the second embodiment includes a first series FET 851, a second series FET 852, a first shunt FET 861 and a second shunt FET 862.

Moreover, in accordance with this change, a total number of resistors connected to a gate and a back gate of each of the series FETs and the shunt FETs is doubled. It should be noted that these resistors are connected in parallel two by two. To be more specific, the SPST switch circuit in the second embodiment further includes first to fourth resistors 821 to 824 and fifth to eighth resistors 831 to 934.

Other components in the SPST switch circuit in the second embodiment are similar to those of the SPST switch circuit in the first embodiment. That is, the SPST switch circuit in the second embodiment includes an input terminal 81, an output terminal 84, a first control terminal 82, a second control terminal 83, a back gate control terminal 88 and a bias power supply 87.

Here, a connection relation of the four FETs 851, 852, 861 and 862 will be described in detail. The input terminal 81 is connected to a drain of the first series FET 851. A source of the first series FET 851 is connected to a drain of the second series FET 852. A source of the second series FET 852 is connected to the output terminal 84. The output terminal 84 is also connected to a drain of the first shunt FET 861. A source of the first shunt FET 861 is connected to a drain of the second shunt FET 862. A source of the second shunt FET is grounded.

It should be noted that the reason why the two FETs 851 and 852 are connected in series as a series section and the two FETs 861 and 862 are connected in series as a shunt section is for the purpose of reduction of the applied voltage to each FET.

A connection relation of the first to eighth resistors 821 to 824 and 831 to 834 will be described in detail. The first control terminal 82 is connected to connection nodes of the first resistor 821 and the second resistor 822. The other connection nodes of the first resistor 821 and the second resistor 822 are connected to gates of the first series FETs 851 and 852. Also, the connection node of the third resistor 823 is connected to a back gate of the first series FET 851. The other connection node of the third resistor 823 is connected to the back gate control terminal 88. Similarly, the connection node of the fourth resistor 824 is connected to a back gate of the second series FET 852, and the other connection node of the fourth resistor 624 is connected to the back gate control terminal 88.

Moreover, the second control terminal 83 is connected to the connection nodes of the fifth resistor 831 and the sixth resistor 832. The other connection node of the fifth resistor 831 is connected to a gate of the first shunt FET 861. Also the other connection node of the seventh resistor 833 is connected to a back gate of the first shunt FET 861. The other connection node of the seventh resistor 833 is further connected to the back gate control terminal 88. Similarly, the other connection node of the sixth resistor 832 is connected to a gate of the second shunt FET 862. The other connection node of the eighth resistor 834 is connected to a back gate of the second shunt FET 862. The other connection node of the eighth resistor 834 is connected to the back gate control terminal 88.

Connection relation other than those described above in the SPST switch circuit in the second embodiment are similar to those of the SPST switch circuit according to the first embodiment and therefore, the detailed description thereof will be omitted.

Here, an operation of the SPST switch circuit according to the second embodiment will be described. If the two shunt FETs 861 and 862 are equivalent in performance, an input signal voltage is divided equally by the two shunt FETs. At this timer assuming that the voltage amplitude of an input AC signal is Vs, voltages applied to a source-back gate parasitic diode and a drain-back gate parasitic diode in each of the shunt FETs are expressed by Vs/4.

Now, if the above consideration is applied to this series connection circuit of the two FETs, when the back gate control terminal is biased to −Vb=−3 V, the condition of voltage to allow the SPST switch circuit to perform a linear operation is expressed by:

−3+Vs/4<+0.7V

namely, Vs<14.8 V.

### Third Embodiment

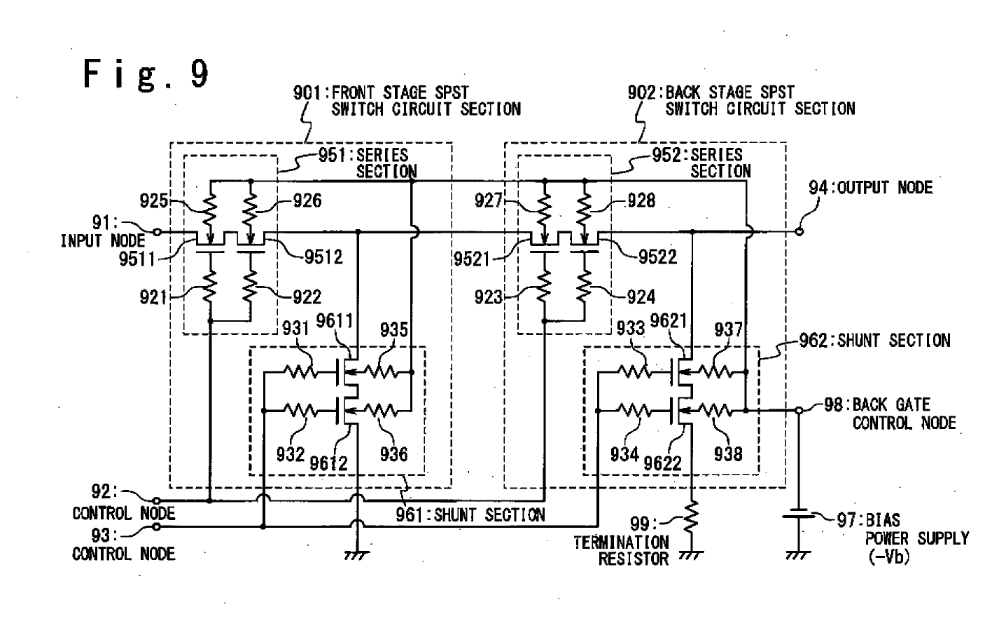

FIG. 9 is a circuit diagram of a high frequency SPST switch circuit according to a third embodiment of the present invention. The SPST switch circuit according to the present embodiment is realized by increasing the number of a series section and a shunt section twice as much as that of the SPST switch circuit according to the second embodiment, and connecting them in series and parallel. These changes were made for the purpose of reduction of an applied voltage to a device.

More specifically, the SPST switch circuit in the third embodiment includes two series sections 951 and 952 and two shunt sections 961 and 962. Here, the first series section 951 includes two series FETs 9511 and 9512. The second series section 952 includes two series FETs 9521 and 9522. The first shunt section 961 includes two shunt FETs 9611 and 9612. The second shunt section 962 includes two shunt FETs 9621 and 9622. In accordance with this change, a total number of resistors connected to gates and back gates of the FETs is doubled in comparison with the second embodiment. To be more specific, the SPST switch circuit in the third embodiment includes sixteen resistors 921 to 928 and 931 to 938.

It should be noted that though the SPST switch circuit in the third embodiment includes two of the shunt sections, a single bias power supply 97 may be provided as shown in FIG. 9, or a plurality thereof may also be provided. Furthermore, the difference from the second embodiment is in that the SPST switch circuit in the third embodiment includes a node resistor 99 connected between one of the shunt sections and the ground.

Other components in the SPST switch circuit in the third embodiment are similar to those of the second embodiment. That is, the SPST switch circuit in the third embodiment includes an input terminal 91, an output terminal 94, a first control terminal 92, a second control terminal 93, and a back gate control terminal 96.

Here, a connection relation of the respective components will be described. Four series FETs 9511, 9512, 9521 and 9522 in the SPST switch circuit according to the present embodiment are connected in series with each other in this order. That is, the input terminal 91 is connected to a drain of the first series FET 9511, a source of the first series FET 9511 is connected to a drain of the second series FET 9512, a source of the second series FET 9512 is connected to a drain of the third series FET 9521, a source of the third series FET 9521 is connected to a drain of the fourth series FET 9522, and a source of the fourth series FET 9522 is connected to the output terminal 94.

Of the four shunt FETs 9611, 9612, 9621 and 9622 in the SPST switch circuit according to the present embodiment, the first shunt FET 9611 and the second shunt FET 9612 are connected in series with each other. Similarly, the third shunt FET 9621 and the fourth shunt FET 9622 are also connected in series with each other. That is, a drain of the first shunt FET 9611 is connected to the source of the second series FET 9512 and the drain of the third series FET 9521, a source of the first shunt FET 9611 is connected to a drain of the second shunt FET 9612, and a source of the second shunt FET 9612 is grounded. A drain of the third shunt FET 9621 is connected to the source of the fourth series FET 9522 and the output terminal 94, a source of the third shunt FET 9621 is connected to a drain of the fourth shunt FET 9622, and a source of the fourth shunt FET 9622 is grounded via the node resistor 99.

Here, a connection relation of the sixteen resistors 921 to 928 and 931 to 938 will be described. The first control terminal 92 is connected to connection nodes of the four resistors 921 to 924. The other connection nodes of the four resistors 921 to 924 are connected to gates of the four series FETs 9511, 9512, 9521 and 9522, respectively. Back gates of the four series FETs 9511, 9512, 9521 and 9522 are connected to connection nodes of the four resistors 925 to 928, respectively. The other connection nodes of the four resistors 925 to 928 are connected to the back gate control terminal 98.

The second control terminal 93 is connected to connection nodes of the four resistors 931 to 934. The other connection nodes of the four resistors 931 to 934 are connected to gates of the four shunt FETs 9611, 9612, 9621 and 9622, respectively. Back gates of the four shunt FETs 9611, 9612, 9621 and 9622 are connected connection nodes of the four resistors 935 to 938, respectively. The other connection nodes of the four resistors 935 to 938 are connected to the back gate control terminal 98.

Moreover, a node on a minus side of the bias power supply 97 is connected to the back gate control terminal 98. The node of the bias power supply 97 on a plus side is grounded.

Attention is paid to the second shunt section 962 in a rear stage of the SPST switch circuit according to the present embodiment. In the second shunt section 962, a voltage is applied to the node resistor 99. Therefore, a voltage applied to each of the two shunt FETs 9621 and 9622 is smaller than a voltage applied to each of the two shunt FETs 9611 and 9612 in the first shunt section 961 in a front stage. As a result, a range of the amplitude voltage of the input signal to allow the SPST switch circuit according to the present embodiment to keep a linear operation is determined only by the first shunt section 961 in the front stage.

It should be noted that, in an example of FIG. 9, different voltage drops are realized between the first shunt section and the second shunt section by arranging the node resistor 99. However, the voltage drops may be differentiated by arranging two different bias power supplies by applying different bias voltages to the first and second shunt sections. As the example, a case is considered that the back gate control terminal 98 is biased to −Vb=−3 V. At this time, in the same manner as the second embodiment, a condition of the input signal amplitude voltage to allow the SPST switch circuit to perform the linear operation is expressed by:

−3+Vs/4<+0.7V

namely, Vs<14.8 V.

### Fourth Embodiment

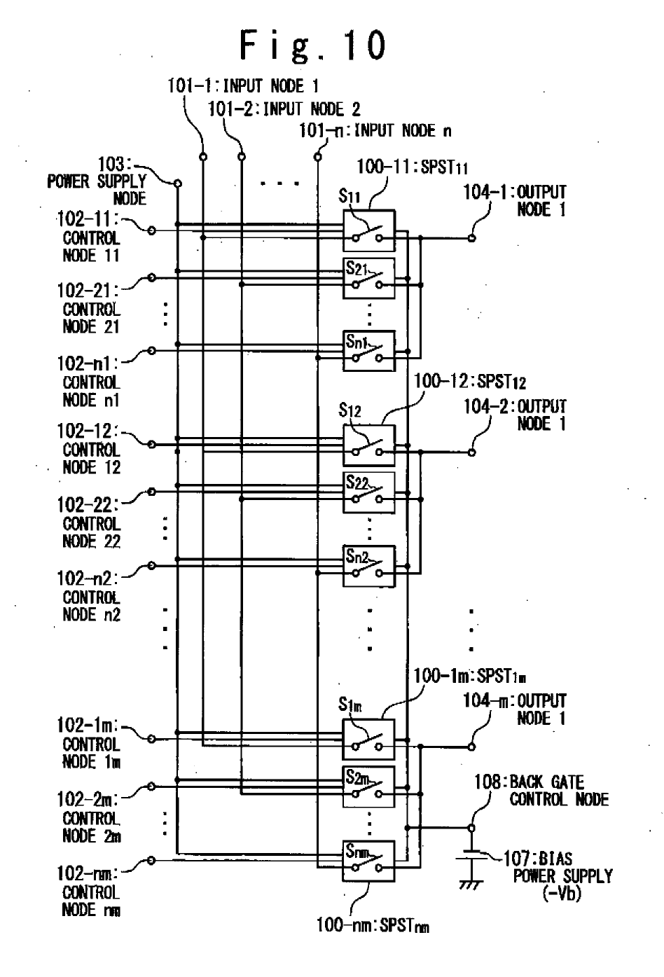

FIG. 10 is a circuit diagram of a matrix switch circuit in a matrix of n rows by m columns according to a fourth embodiment of the present invention. This matrix switch circuit has n×m SPST switch circuits connected in parallel to each other according to the present invention.

The matrix switch circuit includes n input terminals 101-1 to 101-n, m output terminals 104-1 to 104-n, n×m control terminals 102-11 to 102-nm, n×m SPST switch circuits 100-11 to 100-nm, a back gate control terminal 108, and a power supply node 103. Here, the SPST switch circuits according to any one of the first to third embodiments of the present invention is used as each of the n×m SPST switch circuits 100-11 to 100-nm.

The first input terminal 101-1 is connected to a first input section of each of the (1-1)^{th} to (1-m)^{th} SPST switch circuits 100-11 to 100-1m. The second input terminal 101-2 is connected to a first input section of each of the (2-1)^{th} to (2-m)^{th} SPST switch circuits 100-21 to 100-2m. In this way, it is generalized that, in an integer i which is 1 or more and n or less, the i^{th} input terminal 100-i is connected to a first input section in the (i−1)^{th} to (i-m)^{th} SPST switch circuits 100-i1 to 100-im.

The (1-1)^{th} control terminal 102-11 is connected to a second input section of the (1-1)^{th} SPST switch circuit 100-11. The (1-2)^{th} control terminal 102-12 is connected to a second input section of the (1-2)^{th} SPST switch circuit 100-12. Thus, it is generalized that, in an integer which is 1 or more and n or less and an integer j which is 1 or more and m or less, the (i-j)^{th} control terminal 102-ij is connected to a second input section of the (i-j)^{th} SPST switch circuit 100-ij.

The power supply node 103 is connected to a third input section of each of the (1-1)^{th} to (n-m)^{th} SPST switch circuits 100-11 to 100-nm.

The first output terminal 104-1 is connected to a first output section of each of the (1-1)^{th} to (n−1)^{th} SPST switch circuits 100-11 to 100-n1. The second output terminal 104-2 is connected to a first output section of each of the (1-2)^{th} to (n−2)^{th} SPST switch circuits 100-12 to 100-n2. Thus, it is generalized that in an integer j which is 1 or more and m or less, an output terminal j is connected to a first output section of each of the (l-j)^{th} to (n-j)^{th} SPST switch circuit 100-1j to 100-nj.

The back gate control terminal 108 is connected to a second output section of each of the (1-1)^{th} to (n-m)^{th} SPST switch circuits 100-11 to 100-nm.

A connection node of a bias power supply 107 on a minus side is connected to the back gate control terminal 108. A connection point of the bias power supply 107 on a plus side is grounded.

The matrix switch circuit according to the present embodiment is realized by connecting n×m SPST switch circuits according to any of the first to third embodiments of the present invention in a matrix. Accordingly, a range of amplitude voltage of an input signal to allow the matrix switch circuit to perform a linear operation is determined based on a voltage of the input signal applied to the shunt FET in the SPST switch circuits. Accordingly, in the same manner as the first to third embodiments, a predetermined bias is applied to the back gate of the shunt FET in each of the SPST switch circuits via a resistor in the present embodiment. This bias is applied in a reverse direction to a source-back gate parasitic diode and a drain-back gate parasitic diode in the entire shunt FETs in the SPST switch circuit. In this way, it becomes possible to attain an effect such that the range of amplitude voltage of the input signal to allow the (n×m) matrix switch circuit to perform the linear operation is extended without degrading the insertion loss characteristic. An example of specific numerical values in this effect is similar to those of the first to third embodiments, and therefore detailed description thereof will be omitted.

It should be noted that it may be sometimes preferable to integrate the large scaled matrix switch circuit shown in FIG. 10. In such a case, it is necessary to supply power to each of semiconductor elements arranged on the integrated circuit. The power supply node 103 in FIG. 10 can be used for such a purpose.

### Fifth Embodiment

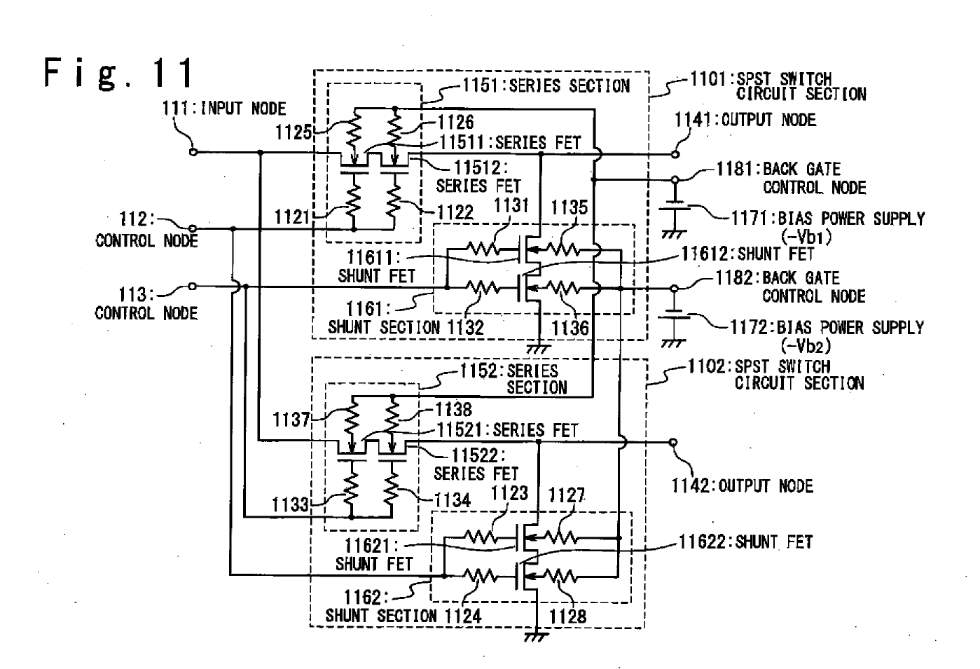

FIG. 11 is a circuit diagram of a matrix switch circuit according to a fifth embodiment of the present invention. This matrix switch circuit is equivalent to a (1×2) matrix switch circuit in a case of n=1 and m=2 in the (n×m) matrix switch circuit according to the fourth embodiment.

The matrix switch circuit according to the present embodiment includes an input terminal 111, a first output terminal 1141, a second output terminal 1142, a first control terminal 112, a second control terminal 113, a first back gate control terminal 1181, a second back gate control terminal 1182, a first bias power supply 1171, a second bias power supply 1172, a first SPST switch circuit section 1101, and a second SPST switch circuit section 1102.

Here, a corresponding relation of the respective components will be described between the fourth embodiment shown in FIG. 10 and the present embodiment shown in FIG. 11. The input terminal 111 in the present embodiment corresponds to the first input terminal 101-1 in the fourth embodiment. The first and second output terminals 1141 and 1142 in the present embodiment correspond to the first and second output terminals 104-1 and 104-2 in the fourth embodiment, respectively. The first and second control terminals 112 and 113 in the present embodiment corresponds to the (1-1)^{th} and (1-2)^{th} control terminals 102-11 and 102-12 in the fourth embodiment, respectively. The first and second back gate control terminals 1181 and 1182 in the present embodiment correspond to the back gate control terminal 108 in the fourth embodiment. The first and second bias power supplies 1171 and 1172 in the present embodiment correspond to the bias power supply 107 in the fourth embodiment. The first and second SPST switch circuit sections 1101 and 1102 in the present embodiment correspond to the (1-1)^{th} and (1-2)^{th} SPST switch circuit sections 100-11 and 100-12 in the fourth embodiment, respectively.

The first SPST switch circuit section 1101 includes a first series section 1151 and a first shunt section 1161. The second SPST switch circuit section 1102 includes a second series section 1152 and a second shunt section 1162. The first series section 1151 includes two series FETs 11511 and 11512 and four resistors 1121, 1122, 1125 and 1126. The first shunt section 1161 includes two shunt FETs 11611 and 11612 and four resistors 1131, 1132, 1135 and 1136. The second series section 1152 includes two series FETs 11521 and 11522 and four resistors 1133, 1134, 1137 and 1138. The second shunt section 1162 includes two shunt FETs 11621 and 11622 and four resistors 1123, 1124, 1127 and 1128.

It should be noted that a power supply terminal corresponding to the power supply node 103 provided in the matrix switch circuit according to the fourth embodiment is not shown in FIG. 11 but may be provided in the matrix switch circuit according to the present embodiment.

Also, the first and second bias power supplies 1171 and 1172 are provided separately in the example of FIG. 11, but the present invention is not limited to this example. For example, the bias power supplies may be combined into one or separate bias power supplies may be provided in the units of series sections and/or shunt sections or in the units of FETs. Here, needless to say, the number of the back gate control terminals is dependent on the number of the bias power supplies.

Here, a connection relation of the components in the matrix switch circuit according to the present embodiment will be described. The input terminal 111 is connected to a first input section in each of the first and second SPST switch circuit sections 1101 and 1102. The first and second control terminals 112 and 113 are connected to a second input section in each of the first and second SPST switch circuit sections 1101 and 1102, respectively. The first and second output sections of the first and second SPST switch circuit sections 1101 and 1102 are connected to the first and second output terminals 1141 and 1142, respectively. The first and second SPST switch circuit sections 1101 and 1102 are connected to the first and second back gate control terminals 1181 and 1182, respectively. A connection node on a minus side of each of the first and second bias power supplies 1171 and 1172 is connected to the first and second back gate control terminals 1181 and 1182, respectively. A connection node on a plus side of each of the first and second bias power supplies 1171 and 1172 is grounded.

Furthermore, as a connection which was absent in the fourth embodiment, the first and second control terminals 112 and 113 are connected to the second and first SPST switch circuit sections 1102 and 1101, respectively.

A connection relation, of the components provided in the first and second SPST switch circuit sections 1101 and 1102 will be described. The first input section of the first SPST switch circuit section 11101, which is connected to the input terminal 111, is connected to a drain of the series FET 11511. A source of the series FET 11511 is connected to a drain of the series FET 11512. A source of the series FET 11512 is connected to the first output section in the first SPST switch circuit section 1101, which is connected to the first output terminal 1141. The output section 1141 is connected to a drain of the shunt FET 11611. A source of the shunt FET 11611 is connected to a drain of the shunt FET 11612. A source of the shunt FET 11612 is grounded.

The second input section of the first SPST switch circuit section 1101, which is connected to the first control terminal 112, is connected to one of connection nodes of the two resistors 1121 and 1122. The other connection nodes of the two resistors 1121 and 1122 are connected to gates of the two series FETs 11511 and 11512, respectively. Back gates of the series FETs 11511 and 11512 are connected to connection nodes of the two resistors 1125 and 1126, respectively. The other connection nodes of the two resistors 1125 and 1126 are connected to the second output section of the first SPST switch circuit section 1101, which is connected to the first back gate control terminal 1181.

Furthermore, the second control terminal 113 is connected to connection nodes of the two resistors 1131 and 1132. The other connection nodes of these resistors 1131 and 1132 are connected to gates of the two shunt FETs 11611 and 11612, respectively. Back gates of the shunt FETs 11611 and 11612 are connected to connection nodes of the two resistors 1135 and 1136, respectively. The other connection nodes of the resistors 1135 and 1136 are connected to the second back gate control terminal 1182.

Moreover, the first input section of the second SPST switch circuit section 1102, which is connected to the input terminal 111, is connected to a drain of the series FET 11521. A source of the series FET 11521 is connected to a drain of the series FET 11522. A source of the series FET 11522 is connected to the first output section in the second SPST switch circuit section 1102, which is connected to the second output terminal 1142. This output section 1142 is also connected to a drain of the shunt FET 11621. A source of the shunt FET 11621 is connected to a drain of the shunt FET 11622. A source of the shunt WET 11622 is grounded.

The second input section of the second SPST switch circuit section 1102, which is connected to the second control terminal 113, is connected to connection nodes of the two resistors 1133 and 1134. The other connection nodes of the resistors 1133 and 1134 are connected to gates of the two series FETs 11521 and 11522, respectively. Back gates of the series FETs 11521 and 11522 are connected to connection nodes of the two resistors 1137 and 1138. The other connection nodes of the resistors 1137 and 1138 are connected to the second output section of the second SPST switch circuit section 1102, which is connected to the first back gate control terminal 1181.

Furthermore, the first control terminal 112 is connected to connection nodes of the two resistors 1123 and 1124. The other connection nodes of these resistors 1123 and 1124 are connected to gates of the two shunt FETs 11621 and 11622, respectively. Back gates of the shunt FETs 11621 and 11622 are connected to connection nodes of the two resistors 1127 and 1128, respectively. The other connection nodes of the resistors 1127 and 1128 are connected to the second back gate control terminal 1182.

In the present embodiment, the effect is attained that a range of input signal amplitude voltage to perform a linear operation is extended by applying biases to the back gate control terminals 1181 and 1182. These biases are applied in a reverse direction to a source-back gate parasitic diode and a drain-back gate parasitic diode. This is because of the same reason as that in the discussion of the (n×m) matrix switch circuit according to the fourth embodiment, and the detailed description thereof will be omitted.

Here, technical meanings in the second to fifth embodiments are summarized. As application examples of the SPST switch circuit according to the first embodiment, the SPST switch circuits which are used more commonly, and the matrix switch circuits realized by connecting these SPST circuits are disclosed in the second to fifth embodiments. In either case, a bias is applied with respect to the back gate control terminal in a reverse direction to the source-back gate parasitic diode and the drain-back gate parasitic diode. It is therefore shown that a range of input signal amplitude voltage to allow a linear operation is extended effectively in the SPST switch circuits and/or the matrix switch circuits according to the respective embodiments.

### Sixth Embodiment

In order to produce the (n×m) matrix switch circuit according to the fourth embodiment on a semiconductor chip, it is preferable to use a circuit for generating a control voltage such as a DC-DC conversion circuit as a bias power supply. The present embodiment discloses an example of an SPST switch circuit which can be used as each of the SPST switch circuit sections in the (n×m) matrix switch circuit according to the fourth embodiment.

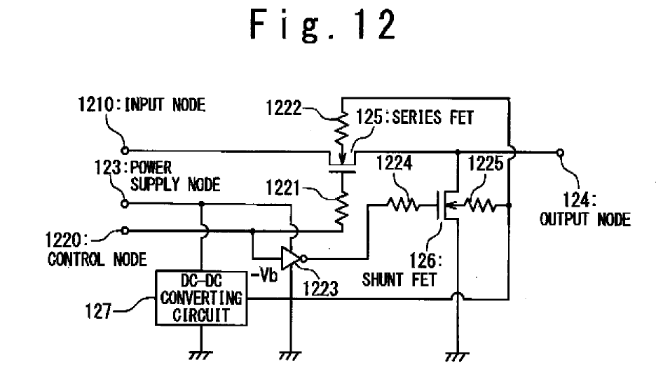

FIG. 12 is a circuit diagram of the SPST switch circuit according to the sixth embodiment of the present invention. The SPST switch circuit is developed from the SPST switch circuit according to the first embodiment and has a control voltage generating circuit incorporated therein. The SPST switch circuit according to the present embodiment includes an input terminal 1210, a control terminal 1220, a power supply node 123, an output terminal 124, a series FET 125, a shunt FET 126, a DC-DC conversion circuit 127, an inverter circuit section 1223, and four resistors 1221, 1222, 1224 and 1225.

The SPST switch circuit according to the present embodiment differs from the SPST switch circuit according to the first embodiment in two points. That is, the SPST switch circuit according to the present embodiment includes the DC-DC conversion circuit 127 in place of the bias power supply 57 in the SPST switch circuit according to the first embodiment. The SPST switch circuit according to the present embodiment also includes the inverter circuit section 1223 in place of the second control terminal 53 in the SPST switch circuit according to the first embodiment. The SPST switch circuit according to the present embodiment further includes the power supply node 123 omitted in the SPST circuit according to the first embodiment.

The input terminal 1210 is connected to a drain of the series FET 125. The series FET 125 has a source which is connected to a drain of the shunt FET 126 and the output terminal 124. A source of the shunt FET 126 is grounded. The control terminal 1220 is connected to an input section of the inverter circuit section 1223 and one connection node of the resistor 1221. An output section of the inverter circuit section 1223 is connected to one connection node of the resistor 1224. The other connection node of the resistor 1221 is connected to a gate of the series FET 125. A back gate of the series FET 125 is connected to one connection node of the resistor 1222. The other connection node of the resistor 1224 is connected to a gate of the shunt FET. A back gate of the shunt FET is connected to one connection node of the resistor 1225. The other connection node of the resistor 1222 and the other connection node of the resistor 1225 are connected to an output section of the DC-DC conversion circuit 127. The power supply node 123 is connected to power supply nodes of the inverter circuit section 1223 and the DC-DC conversion circuit. The other power supply nodes of the inverter circuit section 1223 and the DC-DC conversion circuit are grounded.

The DC-DC conversion circuit in the present embodiment plays a role of the bias circuit according to each of the first to fifth embodiments. That is, the DC-DC conversion circuit applies a voltage to the back gate of each of the FETs 125 and 126 in a reverse direction to a source-back gate parasitic diode and a drain-back gate parasitic diode. It is extremely easy to produce the DC-DC conversion circuit on a silicon semiconductor chip. Since there is no specific limitation for other structures in particular, detailed explanation thereof will be omitted.

Moreover, the inverter circuit section 1223 is provided to make sure that the shunt FET 126 is turned off when the series FET 125 is turned on.

As a semiconductor switch circuit realized at high frequency, a compound semiconductor transistor such as a GaAs field effect transistor is used in general. However, the present invention relates to the four-node FET using silicon MOSFET. By using the SPST switch circuit according to the present invention as each of the SPST switch circuit sections 100-11 to 100-nm in the fourth embodiment, the (n×m) matrix switch according to the present invention can be easily realized on a silicon semiconductor chip. That is, a large-amplitude signal matrix switch IC with a switching logic incorporated therein can be produced to have a single power supply voltage and a minimum number of control terminals.

Although the present invention has been described above in connection with several embodiments thereof, it would be apparent to those skilled in the art that those embodiments are provided solely for illustrating the present invention, and should not be relied upon to construe the appended claims in a limiting sense.

What is claimed is:

1. A switch circuit comprising:
an input section;
an output section;
a first series section having an output and comprising at least a first 4-terminal FET connected between said input section and said output section through the output of said first series section;
a first shunt section comprising at least a second 4-terminal FET connected between an output of said first series section and a ground;
a first control terminal section connected with a gate of said first 4-terminal FET;
a second control terminal section connected with a gate of said second 4-terminal FET;
a back gate control terminal section connected with a back gate of each of said first and second 4-terminal FETs; and
a bias power supply section configured to apply a reverse bias voltage between said back gate control terminal section and said ground.

2. The switch circuit according to claim 1, wherein said bias voltage is applied in a reverse direction of a source—back gate parasitic diode and a drain—back gate parasitic diode in each of said first and second 4-terminal FETs.

3. The switch circuit according to claim 1, wherein said first series section comprises:
a resistance connected between said back gate of said first 4-terminal FET and said back gate control terminal section, and
wherein said first shunt section comprises:
a resistance connected between said back gate of said second 4-terminal FET and said back gate control terminal section.

4. The switch circuit according to claim 1, wherein said first series section comprises:
a plurality of said first 4-terminal FETs which are connected in series,
wherein a gate of each of said plurality of first 4-terminal FETs is connected with said first control terminal, and
wherein a back gate of each of said plurality of first 4-terminal FETs is connected with said back gate control terminal section.

5. The switch circuit according to claim 1, wherein said first shunt section comprises:
a plurality of said second 4-terminal FETs which are connected in series,
wherein a gate of each of said plurality of second 4-terminal FETs is connected with said second control terminal, and
wherein a back gate of each of said plurality of second 4-terminal FETs is connected with said back gate control terminal section.

6. The switch circuit according to claim 1, further comprising:
a second series section comprising at least a third 4-terminal FET connected between the output of said first series section and said output section;
a second shunt section comprising at least a fourth 4-terminal FET connected with said output section; and
a termination resistance connected between said second shunt section and said ground,
wherein a gate of said third 4-terminal FET is connected to said first control terminal section, and a gate of said fourth 4-terminal FET is connected to said second control terminal section,
wherein a back gate of each of said third and fourth 4-terminal FETs is connected to said back gate control terminal section.

7. The switch circuit according to claim 6, wherein said second series section comprises;
a resistance connected between said back gate of said third 4-terminal FET and said back gate control terminal section, and
wherein said second shunt section comprises:
a resistance connected between said back gate of said fourth 4-terminal FET and said back gate control terminal section.

8. The switch circuit according to claim 6, wherein said second series section comprises:
a plurality of said third 4-terminal FETs which are connected in series,
wherein a gate of each of said plurality of third 4-terminal FETs is connected with said first control terminal, and
wherein a back gate of each of said plurality of third 4-terminal FETs is connected with said back gate control terminal section.

9. The switch circuit according to claim 6, wherein said second shunt section comprises:
a plurality of said fourth 4-terminal FETs which are connected in series,
wherein a gate of each of said plurality of fourth 4-terminal FETs is connected with said second control terminal, and
wherein a back gate of each of said plurality of fourth 4-terminal FETs is connected with said back gate control terminal section.

10. The switch circuit according to claim 1, wherein said bias power supply section comprises:
a DC-DC converter circuit configured to convert an input voltage into a fixed voltage.

11. The switch circuit according to claim 1, further comprising:
an inverter circuit section having an input section connected with said first control terminal and an output section connected with said second control terminal.

12. The switch circuit according to claim 1, further comprising:
a second output section;
a second back gate control terminal section;
a second bias power supply section configured to apply a reverse bias voltage between said second back gate control terminal and said ground;
a second series section comprising at least a third 4-terminal FET connected between said input section and said second output section; and
a second shunt section comprising at least a fourth 4-terminal FET connected with said second output section and said ground,
wherein a gate of said third 4-terminal FET is connected to said first control terminal section, and a gate of said fourth 4-terminal FET is connected to said second control terminal section,
wherein a back gate of said third 4-terminal FET is connected to said back gate control terminal section, and a back gate of said fourth 4-terminal FET is connected to said second back gate control terminal section.

13. The switch circuit according to claim 12, wherein said second series section comprises:
a resistance connected between said back gate of said third 4-terminal FET and said back gate control terminal section, and
wherein said shunt section comprises:
a resistance connected between said back gate of said fourth 4-terminal FET and said second back gate control terminal section.

14. The switch circuit according to claim 12, wherein said second series section comprises:
a plurality of said third 4-terminal FETs which are connected in series,
wherein a gate of each of said plurality of third 4-terminal FETs is connected with said first control terminal, and
wherein a back gate of each of said plurality of third 4-terminal FETs is connected with said back gate control terminal section.

15. The switch circuit according to claim 12, wherein said second shunt section comprises:
a plurality of said fourth 4-terminal FETs which are connected in series,
wherein a gate of each of said plurality of fourth 4-terminal FETs is connected with said second control terminal, and
wherein a back gate of each of said plurality of fourth 4-terminal FETs is connected with said second back gate control terminal section.

16. A matrix switch circuit comprising:
n input sections, where n is an integer larger than 1;
m output sections, where m is an integer larger than 1;
a back gate control terminal section;
a bias power supply section configured to apply a reverse bias voltage between said back gate control terminal section and said ground,
(n×m) switch circuits; and
(n×m) control terminals,
wherein an (i, j)^{th} (n≧i≧2, m≧j≧2) of said (n×m) switch circuits is connected with an i^{th} one of said n input sections, a j^{th} one of said m output sections, and an (i, j)^{th} one of said (n×m) control terminals,
wherein each of said (n×m) switch circuits comprises:
a first series section having an output and comprising at least a first 4-terminal FET connected between a corresponding one of said n input sections and a corresponding one of said m output sections through the output of said first series section; and
a first shunt section comprising at least a second 4-terminal FET connected between an output of said first series section and a ground,
wherein a gate of each of said first and second 4-terminal FETS is connected with said back gate control terminal section.
